(19) United States
(12) Patent Application Publication
(10) Pub. No.: US 2021/0233793 A1
(43) Pub. Date: Jul. 29, 2021

(54) SUBSTRATE PROCESSING METHOD AND SUBSTRATE PROCESSING SYSTEM

(71) Applicant: TOKYO ELECTRON LIMITED, Tokyo (JP)

(72) Inventors: Yasutaka HAMA, Hsin-chu City (TW); Nobuaki SHINDO, Miyagi (JP); Shigeru YONEDA, Miyagi (JP)

(21) Appl. No.: 17/156,068

(22) Filed: Jan. 22, 2021

(30) Foreign Application Priority Data
Jan. 29, 2020 (JP) 2020-012461
Nov. 26, 2020 (JP) 2020-196244

(51) Int. Cl. H01L 21/683; H01L 21/67; H01L 21/3065; H01J 37/32

(52) U.S. Cl. CPC H01L 21/6831; H01L 21/67069; H01L 21/3065; H01J 2237/334; H01J 37/32082; H01J 2237/2007; H01J 2237/002; H01J 37/32715

(57) ABSTRACT

A method of processing a substrate includes: (a) placing the substrate on an electrostatic chuck, and applying a direct current voltage to the electrostatic chuck to hold the substrate on the electrostatic chuck; (b) supplying a radio frequency power to an electrode to generate plasma of an inert gas; (c) stopping the application of the direct current voltage to the electrostatic chuck; and (d) gradually decreasing the radio frequency power supplied to the electrode to 0 W.

### CROSS-REFERENCE TO RELATED APPLICATIONS

This application is based upon and claims the benefit of priority from Japanese Patent Application Nos. 2020-012461 and 2020-196244, filed on Jan. 29, 2020 and Nov. 26, 2020, respectively, the entire contents of which are incorporated herein by reference.

### TECHNICAL FIELD

The present disclosure relates to a substrate processing method and a substrate processing system.

### BACKGROUND

Patent Document 1 discloses a method of detaching a wafer held on an electrostatic chuck. In such a method, when residual charges existing on the wafer, which is held on the electrostatic chuck, are removed by using plasma of an inert gas, a charge elimination voltage Vₚₗₐₛₘₐ is applied to a chuck electrode. The charge elimination voltage Vₚₗₐₛₘₐ corresponds to a self-bias potential V_{dc} of the wafer when the plasma is applied.

Patent Document 2 discloses a method of detaching a wafer held on a sample table. In such a method, after starting a process of detaching a sample from the sample table and then stopping supply of radio frequency power for plasma generation, a direct current voltage applied to an electrode for electrostatically holding the wafer on the sample table after a predetermined time elapses is changed from a predetermined value to approximately 0 V. The predetermined value is a value obtained in advance so that the potential of the wafer becomes approximately 0 V when the DC voltage is approximately 0 V. The predetermined time is a time defined based on the time during which charged particles generated by the plasma disappear or the time during which afterglow discharge disappears.

### PRIOR ART DOCUMENTS

### Patent Documents

Patent Document 1: Japanese laid-open publication No. 2004-047511

Patent Document 2: Japanese laid-open publication No. 2018-022756

### SUMMARY

According to one aspect of the present disclosure, a method of processing a substrate includes: (a) placing the substrate on an electrostatic chuck, and applying a direct current voltage to the electrostatic chuck to hold the substrate on the electrostatic chuck; (b) supplying a radio frequency power to an electrode to generating plasma of an inert gas; (c) stopping the application of the direct current voltage to the electrostatic chuck; and (d) gradually decreasing the radio frequency power supplied to the electrode to 0 W.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is an explanatory view showing a schematic configuration of a plasma processing system according to an embodiment.

FIG. 2 is an explanatory diagram showing a wafer detachment process in an embodiment.

FIG. 3 shows time-dependent changes in wafer potential, lifter pin speed, and radio frequency power supplied to a lower electrode in the wafer detachment process.

FIGS. 4A to 4C compare Examples with Comparative Examples by showing time-dependent changes in wafer potential, lifter pin speed, and radio frequency power supplied to the lower electrode in the wafer detachment process.

FIGS. 5A to 5C compare Examples with Comparative Examples by showing time-dependent changes in wafer potential, lifter pin speed, and radio frequency power supplied to the lower electrode in the wafer detachment process while varying a decrease time of the radio frequency power.

FIG. 6 is a graph showing a fluctuation in the wafer potential when the decrease time is varied in a case where the radio frequency power is decreased from 200 W to 0 W.

FIG. 7 is an explanatory diagram showing a wafer detachment process in another embodiment.

FIG. 8 is an explanatory diagram showing a wafer detachment process in another embodiment.

FIG. 9 is an explanatory diagram showing a wafer detachment process in another embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a process of manufacturing a semiconductor device, a plasma processing apparatus generates plasma by exciting a processing gas, and processes a semiconductor wafer (hereinafter referred to as a “wafer”) by the plasma. Such a plasma processing apparatus is provided with an electrostatic chuck (ESC) configured to hold the wafer placed thereon, and performs plasma. processing on the wafer in the state in which the wafer is held by the electrostatic chuck.

By applying a direct current voltage to the electrostatic chuck, a Coulomb force is generated between the electrostatic chuck and the wafer to hold the wafer, in such a case, when the wafer is detached from the electrostatic chuck, charges remain on the wafer. As such, the holding force of the electrostatic chuck with respect to the water is maintained. This makes it difficult to properly detach the wafer, resulting in misalignment or breakage of the wafer. Therefore, in the related art, various measures have been taken against the residual charges at the time of wafer detachment. For example, there is a method of removing residual charges on a wafer using plasma.

However, even if the residual charges on the wafer can be removed to the extent that the wafer is properly detached, particles may adhere to the wafer due to the residual charges. That is, when the wafer is lifted up by lifter pins while the charges remain on the wafer, since the residual charges are changed in position, an electric field changes and the charged particles around the wafer are electrically attracted to the water.

Here, in principle, the charges on the wafer are proportional to the radio frequency power when the plasma is generated. Therefore, in order to remove the residual charges on the wafer, a method of reducing the plasma power may be considered. However, due to the apparatus configuration, there is a limit to controlling the plasma power and the residual charges on the wafer cannot be reduced to zero.

Further, a method of increasing a processing pressure when performing a charge elimination process may be considered to reduce a self-bias potential of a wafer when plasma is applied. However, in this case, it is difficult to sufficiently exchange the processing gas when switching from the plasma processing on the wafer to the charge elimination process. Further, even if the processing pressure of the charge elimination process is increased, the residual charges on the wafer cannot be reduced to zero.

In addition, after the charge elimination process, a method of moving the charges on the wafer to the processing gas may be considered to reduce the residual charges on the wafer while continuously supplying the processing gas. However, in this case, the throughput of wafer processing is significantly degraded.

Further, the detachment method disclosed in Patent Document 1 is a method of removing the residual charges on the wafer with plasma. Specifically, in this method, a voltage corresponding to the self-bias potential of the wafer when the plasma is applied is applied to the chuck electrode to make a potential difference between the wafer and the chuck electrode almost zero, so that an attracting force based on the self-bias is made almost zero. Here, since the self-bias potential of the wafer does not always match for each wafer, it is necessary to accurately measure the self-bias potential in order to carry out the detachment method. However, it is difficult to measure such a self-bias potential, and in practice, the residual charges on the wafer cannot be reduced to zero.

Further, in the detachment method disclosed in Patent Document 2, after the supply of the radio frequency power for plasma generation is stopped, a predetermined time is set in consideration of the disappearance time of charged particles on the wafer so that a direct current voltage to be applied to a sample table (electrostatic chuck) is set to zero. However, when the direct current voltage to be applied to the electrostatic chuck is set to zero after the supply of the radio frequency power is stopped, the potential of the wafer may change significantly to generate a lot of particles.

Here, in a case in which a dry etching process is performed as plasma processing, charges remain in a wiring structure formed on the wafer by the thy etching process. Then, in a subsequent wet process, defects such as elution and corrosion of a wiring metal may occur due to the residual charges. A wet process is, for example, a chemical treatment process of removing a specific layer on the wafer or removing foreign substances on the wafer. Further, in order to suppress the above defects, there is a demand for a method of minimizing the residual charges on the wafer after the dry etching process is completed. However, in the above-described conventional charge elimination process, the residual charges on the wafer cannot be reduced to zero.

As described above, regardless of which method is used, when the wafer is detached from the electrostatic chuck, since the residual charges on the wafer cannot be reduced to zero, particles adhere to the wafer. Further, even after the dry etching process is completed, the residual charges on the wafer cannot be reduced to zero, which may cause defects in the wafer in the subsequent wet process. Therefore, there is a room for improvement in the conventional charge elimination method.

The technique according to the present disclosure suppresses particles from adhering to a substrate held on an electrostatic chuck when the substrate is detached from the electrostatic chuck, to appropriately detach the substrate from the electrostatic chuck. Hereinafter, the present embodiment will be described with reference to the accompanying drawings. Throughout the specification and the drawings, elements having substantially the same functional configuration will be denoted by the same reference numerals and therefore, explanation thereof will be omitted.

<Plasma Processing System>

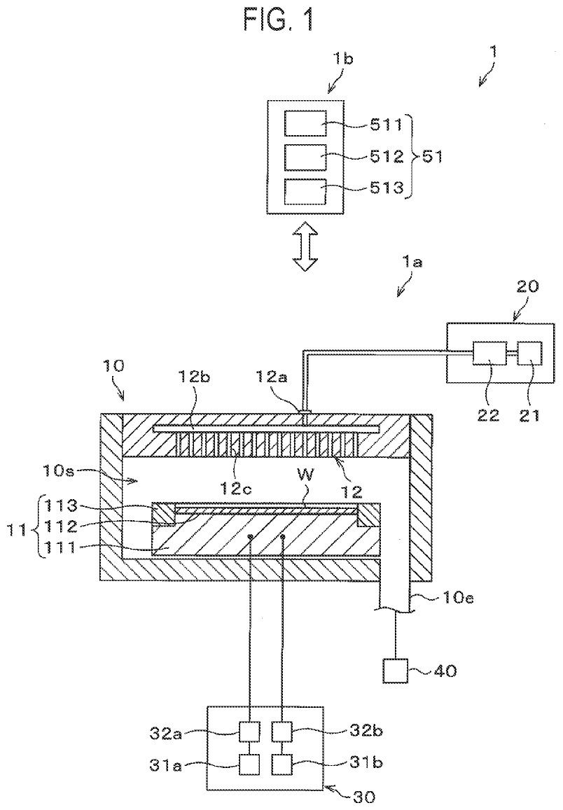

First, a plasma processing system as a substrate processing system according to one embodiment will be described. FIG. 1 is a vertical cross-sectional view showing a schematic configuration of a plasma processing system 1.

In one embodiment, the plasma processing system I includes a plasma processing apparatus 1a and a controller 1b. The plasma processing apparatus 1a includes a plasma processing chamber 10, a gas supply part 20, an RF (radio frequency) power supply part 30, and an exhaust system 40. Further, the plasma processing apparatus 1a includes a support part 11 and an upper electrode shower head 12. The support part 11 is disposed in a lower region of a plasma processing space 10s in the plasma processing chamber 10. The upper electrode shower head 12 is disposed above the support part 11 and may function as a portion of the ceiling of the plasma processing chamber 10.

The support part 11 is configured to support a wafer W in the plasma processing space 10s. In one embodiment, the support part 11 includes a lower electrode 111, an electrostatic chuck 112, and an edge ring 113. The electrostatic chuck 112 is disposed on the lower electrode 111 and is configured to support the wafer W on the upper surface of the electrostatic chuck 112. The edge ring 113 is disposed so as to surround the wafer W on the upper surface of the peripheral edge portion of the lower electrode 111. Further, although not shown, in one embodiment, the support part 11 may include lifter pins that penetrate the support part 11 to be movable up and down while being in contact with a lower surface of the wafer W. Further, although not shown, in one embodiment, the support part 11 may include a temperature adjusting module configured to adjust at least one of the electrostatic chuck 112 and the wafer W to a target temperature. The temperature adjusting module may include a heater, a flow path, or a combination thereof. A temperature adjusting fluid such as coolant or heat transfer gas flows through the flow path.

The upper electrode shower head 12 is configured to supply one or more processing gases from the gas supply part 20 into the plasma processing space 10s. In one embodiment, the upper electrode shower head 12 has a gas inlet 12a, a gas diffusion chamber 12b, and a plurality of gas outlets 12c. The gas inlet 12a is in fluid communication with the gas supply part 20 and the gas diffusion chamber 12b. The plurality of gas outlets 12c is in fluid communication with the gas diffusion chamber 12b and the plasma processing space 10s. In one embodiment, the upper electrode shower head 12 is configured to supply one or more processing gases from the gas inlet 12a to the plasma processing space 10s via the gas diffusion chamber 12b and the plurality of gas outlets 12c.

The gas supply part 20 may include one or more gas sources 21 and one or more flow controllers 22. In one embodiment, the gas supply part 20 is configured to supply one or more processing gases from the respective gas sources 21 to the gas inlet 12a via the respective flow rate controllers 22. Each of the flow rate controllers 22 may include, for example, a mass flow controller or a pressure-controlled flow rate controller. Further, the gas supply part 20 may include one or more flow rate modulation devices that modulate or pulse flow rates of one or more processing gases.

The RF power supply part 30 is configured to supply RF power, for example, one or more RF signals, to one or more electrodes such as the lower electrode 111, the upper electrode shower head 12, or both the lower electrode 111 and the upper electrode shower head 12. With this configuration, plasma is generated from the one or more processing gases supplied into the plasma processing space 10s. Therefore, the RF power supply part 30 may function as at least a portion of a plasma generation part configured to generate the plasma from the one or more processing gases in the plasma processing chamber. In one embodiment, the RF power supply part 30 includes two RF generation parts 31a and 31b and two matching circuits 32a and 32b. In one embodiment, the RF power supply part 30 is configured to supply a first RF signal of a first radio frequency power HF from the first RF generation part 31a to the lower electrode 111 via the first matching circuit 32a. For example, the first RF signal may have a frequency in a range of 27 MHz to 100 MHz.

Further, in one embodiment, the RF power supply part 30 is configured to supply a second RF signal of a second radio frequency power LF from the second RF generation part 31b to the lower electrode 111 via the second matching circuit 32b. For example, the second RF signal may have a frequency in a range of 400 kHz to 13.56 MHz, which is lower than the frequency of the first RF signal. A direct current (DC) pulse generation part may be used instead of the second RF generation part 31b.

Further, although not shown, other embodiments may be considered in the present disclosure. For example, in an alternative embodiment, the RF power supply part 30 may be configured to supply a first RF signal from an RF generation part to the lower electrode 111, supply a second RF signal from another RF generation part to the lower electrode 111, and supply a third RF signal from yet another RF generation part to the lower electrode ill. In addition, in another alternative embodiment, a DC voltage may be applied to the upper electrode shower head 12.

Furthermore, in various embodiments, the amplitude of one or more RF signals (i.e., first RF signal, second RF signal, etc.) may be pulsed or modulated. The amplitude modulation may include pulsing the amplitude of the RF signal between ON and OFF states or between two or more different ON states.

The exhaust system 40 may be connected to, for example, an exhaust port 10e provided at the bottom of the plasma processing chamber 10. The exhaust system 40 may include a pressure valve and a vacuum pump. The vacuum pump may include a turbo molecular pump, a roughing pump, or a combination thereof.

In one embodiment, the controller 1b processes computer-executable instructions that cause the plasma processing apparatus 1a to execute various steps to be described in the present disclosure. The controller 1b may be configured to control various parts of the plasma processing apparatus 1a to perform the various steps to be described herein. In one embodiment, a portion or all of the controller 1b may be included in the plasma processing apparatus 1a. The controller 1b may include, for example, a computer 51. The computer 51 may include, for example, a processing part (CPU: Central Processing Unit) 511, a storage part 512, and a communication interface 513. The processing part 511 may be configured to perform various control operations based on programs stored in the storage part 512. The storage part 512 may include a RAM (Random Access Memory), a ROM (Read Only Memory), an HDD (Hard Disk Drive), an SSD (Solid State Drive), or a combination thereof. The communication interface 513 may communicate with the plasma processing apparatus 1a via a communication line such as a LAN (Local Area Network).

Although various exemplary embodiments have been described above, various additions, omissions, substitutions, and changes may be made without being limited to the above-mentioned exemplary embodiments. It is also possible to combine elements in different embodiments to form other embodiments.

### <Plasma Processing Method>

Next, the plasma processing performed by using the plasma processing system 1 configured as above will be described. The plasma processing is not particularly limited, but may include, for example, a dry etching process, a film forming process, and the like.

First, the wafer W is loaded into the plasma processing chamber 10, and is placed on the electrostatic chuck 112 with the up-down movement of the lifter pins. After that, by applying a DC voltage to the electrode of the electrostatic chuck 112, the wafer W is electrostatically held by the electrostatic chuck 112 by virtue of a Coulomb force. Further, after the wafer W is loaded into the plasma processing chamber 10, the interior of the plasma processing chamber 10 is depressurized to a predetermined degree of vacuum by the exhaust system 40.

Subsequently, the processing gas is supplied from the gas supply part 20 to the plasma processing space 10s via the upper electrode shower head 12. Further, the RF power supply part 30 supplies the first radio frequency power HF for plasma generation to the lower electrode 111 to excite the processing gas to generate plasma. At this time, the RF power supply part 30 may supply the second radio frequency power LF for ion attraction. Then, the wafer W is subjected to plasma processing by the action of the generated plasma.

In addition, during the plasma processing, the temperature of the wafer W held on the electrostatic chuck 112 is adjusted by the temperature adjusting module. At this time, in order to efficiently transfer heat to the wafer W, a heat transfer gas such as a He gas or an Ar gas is supplied toward the back surface of the wafer W held on the upper surface of the electrostatic chuck 112.

When terminating the plasma processing, first, the supply of the first radio frequency power HF from the RF power supply part 30 and the supply of the processing gas from the gas supply part 20 are stopped. Further, when the second radio frequency power LF has been supplied during the plasma processing, the supply of the second radio frequency power LF is also stopped. Subsequently, the supply of the heat transfer gas toward the back surface of the wafer W is stopped, and the holding of the wafer W by the electrostatic chuck 112 is ceased.

Thereafter, the wafer W is raised by the lifter pins to detach the wafer W from the electrostatic chuck 112. Details of the method of detaching the wafer W will be described later. Then, the wafer W is unloaded from the plasma processing chamber 10, and a series of plasma processing on the wafer W is completed.

<Wafer Detachment Method>

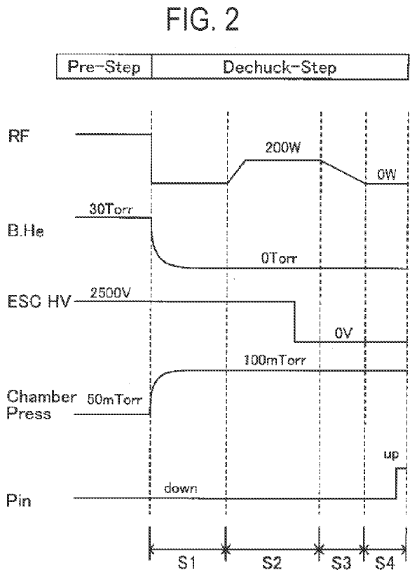

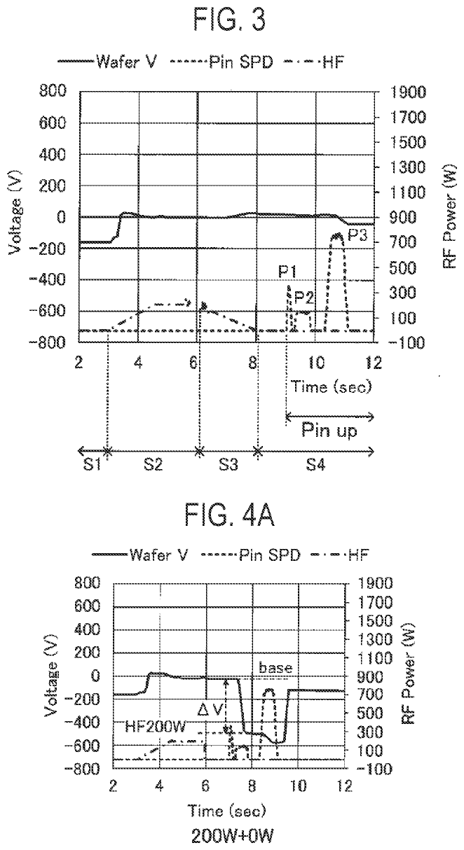

Next, a method of detaching the wafer W from the electrostatic chuck 112 after performing the plasma processing on the wafer W as described above will be described with reference to FIGS. 2 and 3.

FIG. 2 is an explanatory diagram showing a wafer detachment process of detaching the wafer W. FIG. 2 shows a time-dependent change of the following parameters. “RF” represents radio frequency power HF supplied to the lower electrode 111, “B.He” represents a. pressure of the heat transfer gas (the He gas in this embodiment). “ESC HV” represents a DC voltage applied to the electrostatic chuck 112. “Chamber Press” represents an internal pressure of the plasma processing chamber 10. “Pin” represents a timing for raising and lowering the lifter pins. Further, in FIG. 2, “Dechuck-Step” represents the wafer detachment process, and “Pre-Step” represents a process (including the plasma processing) before the wafer W is detached. The numerical values of power, voltage, and pressure in FIG. 2 are examples and may be changed according to a recipe of the plasma processing.

FIG. 3 shows time-dependent changes of the potential of the wafer W (“Wafer V” in FIG. 3), the speed of the lifter pins (“Pin SPD” in FIG. 3), and the radio frequency power (“HF” in FIG. 3) supplied to the lower electrode 111 in the wafer detachment process. FIG. 3 shows time-dependent changes of the above parameters from 2 seconds after the start time of the water detachment process (the start time of “Dechuck-Step” in FIG. 2) is set to 0 second. In FIG. 3, the numerical values of the potential of the wafer W (“Voltage” in FIG. 3) and the radio frequency power (“RF Power” in FIG. 3) are also examples and may be changed according to a recipe of the plasma processing.

The following is a description on the wafer detachment process by dividing into steps S1 to S4.

(Step S1)

Step S1 is a step immediately after the plasma processing is completed. In step S1, the radio frequency power becomes 0 W as the supply of the radio frequency power to the lower electrode 111 is stopped, and the pressure of the heat transfer gas becomes 0 Torr as the supply of the heat transfer gas to the back surface of the wafer W is stopped. Further, the Ar gas is supplied from the gas supply part 20 at a flow rate of, for example, 600 sccm, and the internal pressure of the plasma processing chamber 10 is increased from 50 mTorr to a range of 100 mTorr to 250 mTorr (in the present embodiment, 100 mTorr). The reason for increasing the internal pressure of the plasma processing chamber 10 in this way is to reduce the self-bias potential of the wafer W to facilitate detachment of the wafer W. Further, in step S1, the DC voltage is continuously applied to the electrostatic chuck 112 so that the wafer W is held on the electrostatic chuck 112.

(Step S2)

In step S2, the radio frequency power HF is supplied to the lower electrode 111 to generate plasma of an inert gas. Specifically, the inert gas composed of an Ar gas alone is supplied from the gas supply part 20 into the plasma processing space 10s via the upper electrode shower head 12. Further, the radio frequency power is supplied from the II power supply part 30 to excite the inert gas to generate the plasma. When the radio frequency power is changed suddenly, the matching circuit 32a may not sufficiently follow such a sudden change, which may make the plasma unstable. In order to prevent this, the radio frequency power is gradually increased from 0 W to, for example, a range of 100 W to 400 W (in the present embodiment, 200 W). The basis for the radio frequency power of 100 W to 400 W will be described later.

Further, in step S2, the application of the DC voltage to the electrostatic chuck 112 is stopped. The timing at which the application of the DC voltage is stopped is after a predetermined time has elapsed after the radio frequency power reaches 200 W and the plasma is generated. This predetermined time is sufficient for the radio frequency power to be stabilized, and is, for example, 2 seconds. Then, after the application of the DC voltage to the electrostatic chuck 112 is stopped, the generated plasma is used to remove the charges remaining on the wafer.

(Step S3)

In step S3, the radio frequency power supplied to the lower electrode 111 is gradually decreased to 0 W. The timing at which the decrease in the radio frequency power starts is after a predetermined time (hereinafter referred to as a “delay time”) has elapsed after the application of the DC voltage to the electrostatic chuck 112 is stopped. The delay time is provided in order to suppress the influence of a change in electric field around the wafer W by stopping the application of the DC voltage to the electrostatic chuck 112 in a state where the plasma is stably generated. The delay time is, for example, 1 second. Then, the radio frequency power is decreased at a constant speed, that is, linearly. The time required for decreasing the radio frequency power is, for example, 0.5 seconds to 4 seconds. The basis for this decrease time of 0.5 seconds to 4 seconds will be described later.

Here, as a result of the earnest research conducted by the present inventors, it has been found that when the radio frequency power supplied to the lower electrode 111 is instantaneously decreased from 200 W to 0 W, the charges due to the self-bias potential remain on the wafer W so that the potential of the wafer W cannot be completely reduced to zero. The self-bias potential of the wafer W is proportional to the radio frequency power when generating plasma. Therefore, the present inventors considered that the residual charges on the water W can be decreased by gradually decreasing the radio frequency power supplied to the lower electrode 111. Then, as shown in FIG. 3, it has been found that the residual charges on the water W can be made substantially zero by gradually decreasing the radio frequency power in step S3 and making the potential of the wafer W substantially zero.

(Step S4)

In step S4, the wafer W is raised by the lifter pins, and is separated and detached from the electrostatic chuck 112. Referring to FIG. 3, there are three peaks P1 to P3 according to the speed of the lifter pins. The first peak P1 is the speed of the lifter pins until the lifter pins come into contact with the lower surface of the wafer W. The speed of the lifter pins is increased in order to improve throughput. The second peak P2 is the speed of the lifter pins when the wafer W is detached and raised from the electrostatic chuck 112 immediately after the lifter pins come into contact with the lower surface of the wafer W. The third peak P3 is the speed of the lifter pins when the wafer W is raised to a position where the wafer W is unloaded after the wafer W is detached from the electrostatic chuck 112. At this time, no attracting force is generated between the electrostatic chuck 112 and the wafer W, and the speed of the lifter pins is increased in order to improve throughput,

Here, if the charges remain on the wafer W at the second peak P2, the capacitance between the upper surface of the electrostatic chuck 112 and the wafer W decreases when the wafer W is detached from the electrostatic chuck 112, and the potential of the wafer W fluctuates accordingly. In this respect, in the present embodiment, since the residual charges on the wafer W is made substantially zero by gradually decreasing the radio frequency power in step 53, the fluctuation in the potential of the wafer W becomes substantially zero,

According to the above embodiment, since the radio frequency power supplied to the lower electrode 111 is gradually decreased in step S3, the residual charges on the wafer W is made substantially zero when the wafer W is detached from the electrostatic chuck 112, and therefore, the potential of the wafer W can be made substantially zero. That is, the charge elimination process on the wafer W after the plasma processing can be appropriately performed. Therefore, it is possible to prevent particles from adhering to the wafer W. The particles are composed of, for example, Si O, C, Al, or the like, and have a diameter of, for example, 20 nm to 100 nm.

Further, since the potential of the wafer W can be made substantially zero in this way, the Coulomb force acting between the electrostatic chuck 112 and the wafer W can be reduced, and smooth lift-up can be performed when the wafer W is raised by the lifter pins, Further, this makes it possible to prevent the water W from being damaged when the wafer W is detached from the electrostatic chuck 112. Further, it is possible to prevent a deviation of the center position of the wafer W,

[Effects of the Present Embodiment]

According to the above embodiment, the potential of the wafer W can be made substantially zero as described above. This effect will be described below.

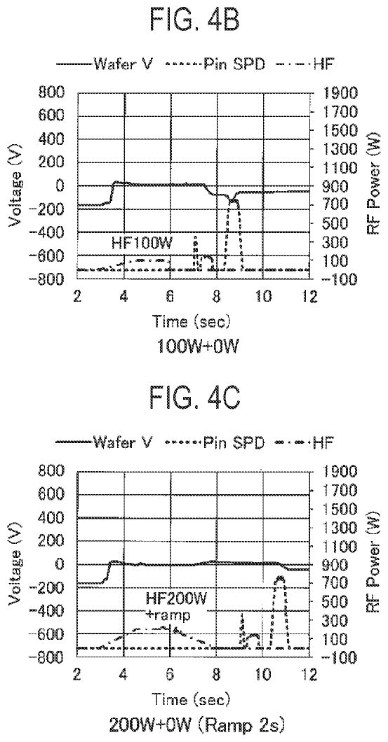

FIGS. 4A to 4C compare Examples of the present embodiment (hereinafter referred to as “Examples”) with Comparative Examples by showing time-dependent changes of potential of the wafer W, the speed of the lifter pins, and the radio frequency power supplied to the lower electrode 111 in the wafer detachment process. FIG. 4A shows Comparative Example 1, in which the internal pressure of the plasma processing chamber 10 is 100 mTorr and the radio frequency power supplied to the lower electrode 111 is instantaneously decreased from 200 W to 0 W. FIG. 4B shows Comparative Example 2, in which the internal pressure of the plasma processing chamber 10 is 250 mTorr and the radio frequency power supplied to the lower electrode 111 is instantaneously decreased from 100 W to 0 W. FIG. 4C shows Example 1, in which the internal pressure of the plasma processing chamber 10 is 100 mTorr and the radio frequency power supplied to the lower electrode 111 is gradually decreased from 200 W to 0 W over 2 seconds.

As described above, if the charges remain on the wafer W at the second peak P2 at the speed of the lifter pins, the potential of the wafer W fluctuates when the wafer W is detached from the electrostatic chuck 112. Therefore, the potential fluctuation of the wafer W is compared between Example 1 and Comparative Examples 1 and 2. The potential fluctuation of the wafer W is represented as “ΔV” in FIG. 4A.

In Comparative Example 1 shown in FIG. 4A, the potential fluctuation ΔV of the wafer W was −470 V, and in Comparative Example 2 shown in FIG. 4B, the potential fluctuation ΔV of the wafer W was −95 V. This result means that in Comparative Examples 1 and 2, the charges remain on the wafer W when the wafer W is detached.

On the other hand, in Example 1 shown in FIG. 4C, the potential fluctuation ΔV of the wafer W was −10 V. This “−10 V” is in an allowable range of error and is substantially zero. Therefore, in Example 1, the residual charges when the wafer W is detached are substantially zero, which makes it possible to prevent particles from adhering to the wafer W.

Further, Comparative Example 1 shown in FIG. 4A and Example 1 shown in FIG. 4C were performed on a plurality of wafers W. Then, the number of particles adhering to the plurality of wafers W was measured, and the average value per wafer W was calculated as 8.5 in Comparative Example 1 and 3.5 in Example 1. Therefore, it was found that in the present embodiment, it was possible to prevent particles from adhering to the wafer W in reality.

<Conditions in Step S3>

Next, a suitable range of the decrease time and the radio frequency power at the start of decrease when the radio frequency power supplied to the lower electrode 111 is gradually decreased in step S3 as described above will be explained.

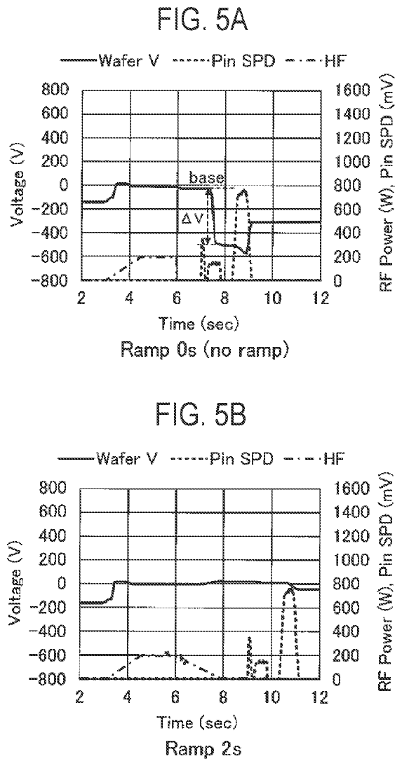

FIGS. 5A to 5C compare Examples with Comparative Examples by showing time-dependent changes of the potential of the wafer W, the speed of the lifter pins, and the radio frequency power supplied to the lower electrode 111 in the wafer detachment process while varying the decrease time. FIG. 5A is the same Comparative Example as Comparative Example 1 shown in FIG. 4A, in which the decrease time is 0 seconds, that is, the radio frequency power is instantaneously decreased. FIG. 5B is the same Example as Example 1 shown in FIG. 4C, in which the decrease time is 2 seconds. FIG. 5C shows Example 2 in which the decrease time is 4 seconds. In FIGS. 5A to 5C, the radio frequency power was decreased from 200 W to 0 W.

In Comparative Example 3 shown in FIG. 5A, the potential fluctuation ΔV of the wafer W was −470 V. Therefore, in Comparative Example 3, the charges remained on the wafer W when the wafer W was detached.

On the other hand, in the Example shown in FIG. 5B, the potential fluctuation ΔV of the wafer W was −10 V, and in Example 2 shown in FIG. 5C, the potential fluctuation ΔV of the wafer W was 23 V. Each of these “−10 V” and “23 V” is in an allowable range of error, and is substantially zero. Therefore, in Examples 1 and 2, the residual charges when the wafer W is detached were substantially zero. Thus, it is possible to prevent particles from adhering to the wafer W.

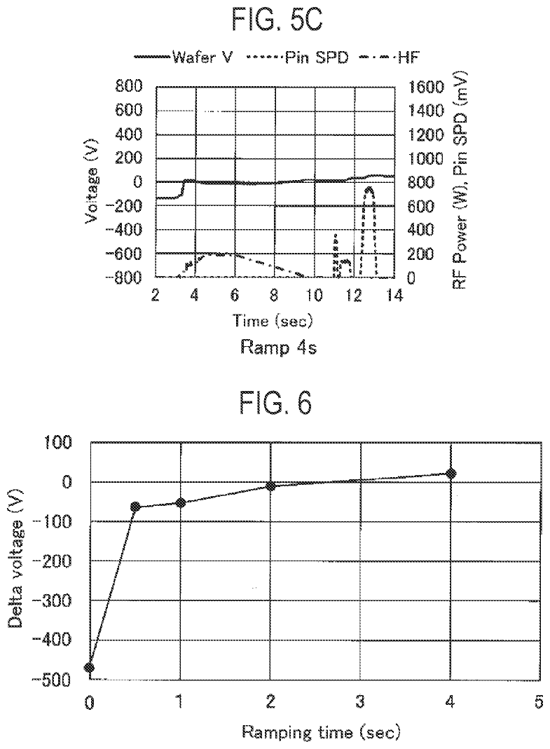

FIG. 6 is a graph showing the potential fluctuation ΔV of the wafer W when the decrease time is varied in a case where the radio frequency power is decreased from 200 W to 0 W. In FIG. 6, the horizontal axis represents the decrease time, and the vertical axis represents the potential fluctuation ΔV of the wafer W.

Referring to FIG. 6, it can be seen that when the decrease time of the radio frequency power is 0.5 seconds to 4 seconds, the potential fluctuation ΔV of the wafer W is 65 V or less in absolute value, which is substantially zero. In other words, the suitable range of the decrease time is 0.5 seconds to 4 seconds. If the decrease time is too short, it means that charges on the wafer W cannot be completely eliminated, by which the lower limit value of the decrease time is determined. Further, if the decrease time is too long, plasma for electric charge elimination cannot be maintained, which also means that charges on the wafer W cannot be completely eliminated, by which the upper limit value of the decrease time is determined.

Here, since the radio frequency power and the self-bias potential of the wafer W are proportional to each other, the larger the radio frequency power, the larger the self-bias potential of the wafer W. Therefore, the radio frequency power is preferably as small as possible. As a result of the earnest research conducted by the present inventors, it has been found that the upper limit value of the radio frequency power is 400 W. Further, in reality, there is a limit to decreasing the radio frequency power from the viewpoint of plasma stability. Further, as a result of the earnest research conducted by the present inventors, it has been found that the lower limit value of the radio frequency power is 100 W. Therefore, the suitable range of the radio frequency power at the start of decrease is 100 W to 400 W.

[Another Embodiment]

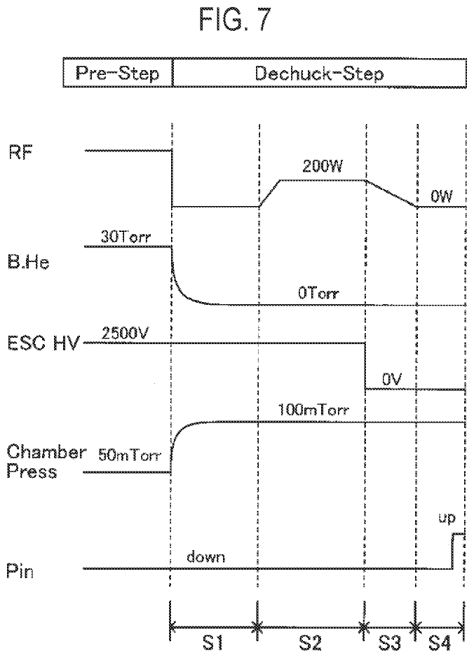

In the above embodiments, after the delay time elapses after the application of the DC voltage to the electrostatic chuck 112 is stopped in step S2 as shown in FIG. 2, the decrease of the radio frequency power to the lower electrode 111 in step S3 is started. In this regard, the delay time may be zero as shown in FIG. 7. However, it is preferable to provide the delay time since the decrease of the radio frequency power can be started after ensuring the decrease of a change in the electric field around the wafer W due to the application of the DC voltage to the electrostatic chuck 112.

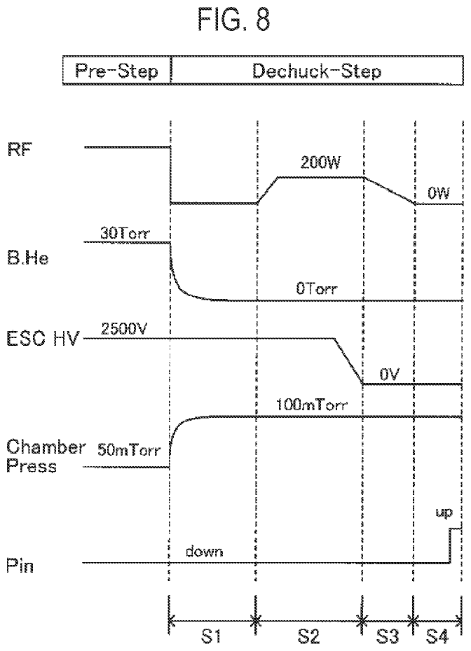

Further, in the above embodiments, the application of the DC voltage to the electrostatic chuck 112 is instantaneously stopped in step S2 as shown in FIG. 2, but the application of the DC voltage may be gradually decreased and stopped as shown in FIG. 8. In such a case, since the change in the electric field around the wafer W can be minimized, particles electrically attracted to the wafer W can be reduced.

Further, the plasma processing apparatus 1a of the above embodiments is configured to supply the first radio frequency power HF to the lower electrode 111, but the first radio frequency power HF may be supplied to the upper electrode shower head 12. In such a case, the second radio frequency power LF may be supplied to the lower electrode 111.

Even when the first radio frequency power HF is supplied to the upper electrode shower head 12 in this manner, the self-bias potential of the wafer when the plasma is applied is not zero. Therefore, by gradually decreasing the radio frequency power supplied to the lower electrode 111 in step S3 as in the above embodiments, the effect that the potential of the wafer W can be made substantially zero can be achieved.

However, the self-bias potential of the wafer at the time of application of the plasma is larger when the first radio frequency power HF is supplied to the lower electrode 111. Therefore, the above-described effect that the potential of the wafer W can be made substantially zero becomes even greater.

In the above embodiments, when the wafer W is detached from the electrostatic chuck 112, the radio frequency power HF having a higher frequency is supplied to the lower electrode 111, but the radio frequency power LF having a lower frequency may be supplied to the lower electrode 111. Even in such a case, the same effects as that of the above embodiments can be provided. That is, the potential of the wafer W can be made substantially zero. However, the radio frequency power supplied when the wafer W is detached from the electrostatic chuck 112 is either one of the radio frequency power HF or the radio frequency power LF.

[Another Embodiment]

In the above embodiments, the charges on the wafer W are removed by the plasma generated in step S2, and the residual charges due to the self-bias potential of the wafer W can be reduced by gradually decreasing the radio frequency power supplied to the lower electrode 111 in step S3. As a result, the potential of the wafer W can be made substantially zero. However, depending on the surface conditions of the electrostatic chuck 112, even when the application of the DC voltage to the electrostatic chuck 112 is stopped, charges may remain on the surface of the electrostatic chuck 112. For example, there is a case where deposits adhere to the surface of the electrostatic chuck 112 and the surface of the electrostatic chuck 112 is deformed by repeated plasma processing. In such a case, the charges may remain on the wafer W due to the influence of the charges remaining on the surface of the electrostatic chuck 112.

Therefore, in the present embodiment, the wafer W is separated and detached from the electrostatic chuck 112 before the plasma generated in step S2 is extinguished, and then the radio frequency power supplied to the lower electrode 111 is gradually decreased to extinguish the plasma. In such a case, as a result of the earnest research conducted by the present inventors, it has been found that the charges on the wafer W can be removed without being affected by the surface state of the electrostatic chuck 112, and the residual charges, which are generated when the plasma is generated in step S2 and are due to the self-bias potential of the wafer W, can be reduced. As a result, the potential of the wafer W can be further ensured of being made substantially zero.

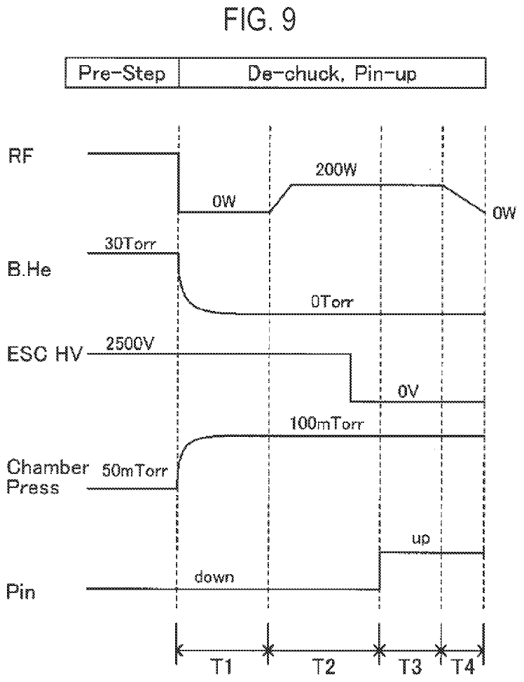

Next, in the present embodiment, a method of detaching the wafer W from the electrostatic chuck 112 will be described with reference to FIG. 9. FIG. 9 is an explanatory diagram showing a wafer detachment process. FIG. 9 corresponds to FIG. 2 of the above embodiment, in which respective parameters used herein correspond to those shown in FIG. 2,

The following is a description on the wafer detachment process by dividing into steps T1 to T4 as in the above embodiment.

(Step T1)

Step T1 is a step immediately after the plasma processing is completed. In step T1, the same process as in step S1 of the above embodiment is performed.

(Step T2)

In step T2, the radio frequency power LF is supplied to the lower electrode 111 to generate plasma of an inert gas. In step T2, as the radio frequency power, the second radio frequency power LF is used instead of the first radio frequency power HF in step S2 of the above embodiment. Except for this point, in step T2, the same process as in step S2 of the above embodiment is performed.

(Step T3)

In step T3, while maintaining the supply of the radio frequency power to the lower electrode 111 in step T2, that is, while maintaining the generation of the plasma, the wafer is raised by the lifter pins and is separated and detached from the electrostatic chuck 112.

(Step T4)

In step T4, the radio frequency power supplied to the lower electrode 111 is gradually decreased to 0 W, and the plasma is extinguished. Here, as in the above embodiments, when the radio frequency power supplied to the lower electrode 111 is instantaneously decreased from 200 W to 0 W, the charges due to the self-bias potential remain on the wafer W, and accordingly, the potential of the wafer W cannot be completely reduced to zero. Therefore, the residual charges on the wafer W is decreased by gradually decreasing the radio frequency power supplied to the lower electrode 111. Then, by gradually decreasing the radio frequency power in step T4, the residual charges on the wafer W can be made substantially zero, and accordingly, the potential of the wafer W can be made substantially zero. Moreover, at this time, the residual charges on the wafer W can be made substantially zero without being affected by the surface conditions of the electrostatic chuck 112.

According to the above embodiment, after the wafer W is separated and detached from the electrostatic chuck 112 in step T3, since the radio frequency power supplied to the lower electrode 111 is gradually decreased in step T4, the residual charges on the wafer W can be made substantially zero, and accordingly, the potential of the wafer W can be made substantially zero. That is, the charge elimination process on the wafer W after the plasma processing can be appropriately performed.

As described above, in a case where the dry etching process is performed as the plasma processing, if the charges remain in a wiring structure on the wafer W, defects such as elution and corrosion of a wiring metal may occur due to the residual charges in a subsequent wet process. According to the present embodiment, since the potential of the water W after the plasma processing can be made substantially zero, such defects can be suppressed.

According to the present disclosure in some embodiments, it is possible to appropriately perform a charge elimination process on a substrate after plasma processing.

It should be noted that the embodiments disclosed herein are exemplary in all respects and are not restrictive. The above-described embodiments may be omitted, replaced or modified in various forms without departing from the scope and spirit of the appended claims.

What is claimed is:

1. A method of processing a substrate, comprising:
(a) placing the substrate on an electrostatic chuck, and applying a direct current voltage to the electrostatic chuck to hold the substrate on the electrostatic chuck;
(b) supplying a radio frequency power to an electrode to generate plasma of an inert gas;
(c) stopping the application of the direct current voltage to the electrostatic chuck; and
(d) gradually decreasing the radio frequency power supplied to the electrode to 0 W.

2. The method of claim 1, further comprising: after (d), (e) raising the substrate to separate the substrate from the electrostatic chuck.

3. The method of claim 2, further comprising: between (a) and (b),
(f) supplying a first radio frequency power to the electrode to perform a plasma processing on the substrate; and
(g) stopping the supply of the first radio frequency power,

4. The method of claim 3, wherein (f) includes supplying the first radio frequency power and a second radio frequency power having a frequency different from a frequency of the first radio frequency power to the electrode.

5. The method of claim 4, wherein the frequency of the first radio frequency power is higher than the frequency of the second radio frequency power.

5. The method of claim 5, further comprising: between (a) and (b),
(h) supplying a heat transfer gas to a back surface of the substrate; and
(i) stopping the supply of the heat transfer gas.

7. The method of claim 6, wherein in (d), the radio frequency power is gradually decreased at an interval of 0.5 seconds to 4 seconds.

8. The method of claim 7, wherein in (d), the radio frequency power is gradually decreased at a constant speed.

9. The method of claim 1, further comprising: between (c) and (d), raising the substrate to separate the substrate from the electrostatic chuck.

10. The method of claim 1, further comprising: between (a) and (b),
(f) supplying a first radio frequency power to the electrode to perform a plasma processing on the substrate; and
(g) stopping the supply of the first radio frequency power.

11. The method of claim 1, further comprising: between (a) and (b),
(h) supplying a heat transfer gas to a back surface of the substrate; and
(i) stopping the supply of the heat transfer gas.

12. The method of claim 1, wherein in (d), the radio frequency power is gradually decreased at an interval of 0.5 seconds to 4 seconds.

13. The method of claim 1, wherein in (d), the radio frequency power is gradually decreased at a constant speed.

14. The method of claim 1, wherein in (c), the direct current voltage is gradually decreased.

15. The method of claim 1, wherein in (b), the radio frequency power is gradually increased.

16. The method of claim 1, wherein in (b), the inert gas is composed of an argon gas alone.

17. The method of claim 1, wherein in (b), the radio frequency power is 100 W to 400 W.

18. The method of claim 1, wherein the electrode is a lower electrode disposed below the electrostatic chuck.

19. The method of claim 1, wherein the electrode is an upper electrode disposed above the electrostatic chuck.

20. A substrate processing system comprising:
an electrostatic chuck configured to hold a substrate;
an electrode;
a radio frequency power supply part configured to supply a radio frequency power to the electrode;
a gas supply part configured to supply an inert gas; and
a controller configured to control the electrostatic chuck, the radio frequency power supply part, and the gas supply part so as to perform a process including:
(a) placing the substrate on the electrostatic chuck, and applying a direct current voltage to the electrostatic chuck to hold the substrate on the electrostatic chuck;
(b) supplying the radio frequency power to the electrode to generate plasma of the inert gas;
(c) stopping the application of the direct current voltage to the electrostatic chuck; and
(d) gradually decreasing the radio frequency power supplied to the electrode to 0 W.
